(19) United States
(12) Patent Application Publication
(10) Pub. No.: US 2020/0081063 A1
(43) Pub. Date: Mar. 12, 2020

(54) TEST CIRCUIT AND TEST METHOD

(71) Applicants: Kabushiki Kaisha Toshiba, Tokyo (JP); Toshiba Electronic Devices & Storage Corporation, Tokyo (JP)

(72) Inventor: Hirotada Furuta, Meguro Tokyo (JP)

(21) Appl. No.: 16/286,867

(22) Filed: Feb. 27, 2019

(30) Foreign Application Priority Data
Sep. 6, 2018 (JP) 2018-167228

(51) Int. Cl. G01R 31/3177; G01R 31/317

(52) U.S. Cl. CPC G01R 31/3177; G01R 31/31727

(57) ABSTRACT

A test circuit includes flip-flops operating in synchronization with a clock signal, a timing adjustment circuit to generate a first set signal that provides a command that sets output signals from the flip-flops at a predetermined logic, and a second set signal that provides a command that detects a fault in the output signals from the flip-flops, and to set timing for cancellation of the command of the second set signal, the timing being delayed by n cycles of the clock signal from timing for cancellation of the command of the first set signal, and a fault detection circuit to output a fault detection signal during a period of time from the cancellation of the command of the first set signal to the cancellation of the command of the second set signal, if there is an output signal having a different logic in the output signals from the flip-flops.

### CROSS REFERENCE TO RELATED APPLICATIONS

This application is based upon and claims the benefit of priority from the prior Japanese Patent Application No. 2018-167228, filed on Sep. 6, 2018, the entire contents of which are incorporated herein by reference.

### FIELD

Embodiments described herein relate generally to test circuits and test methods.

### BACKGROUND

Semiconductor chips that deal with digital signals include many flip-flops. For example, a register circuit that stores data includes a plurality of flip-flops. A flip-flop operates in synchronization with a clock signal CLK. However, the output signal of the flip-flop may sometimes be stuck at one logic, which causes a fault. This stuck-at fault may happen only when a specific logic signal is outputted by the flip-flop.

In order to detect such faults, a process of changing the logic of data inputted to each flip-flop and detecting the output of each flip-flop needs to be performed for all of the flip-flops. This cause a problem in that the time required for fault detection may be long.

Another detection method includes reading data written to each flip-flop of a register circuit and checking whether target data is correctly written. However, reading data that has been written to the register circuit may not be desirable in terms of security.

### BRIEF DESCRIPTION OF THE DRAWINGS

FIG. 1 is a circuit diagram of a test circuit according to a first embodiment.

FIG. 2 is a circuit diagram illustrating an example of a timing adjustment circuit.

FIG. 3 is an operation timing diagram of the test circuit shown in FIG. 1.

FIG. 4 is a circuit diagram of a test circuit including a flip-flop with a reset terminal and a flip-flop with a set terminal.

FIG. 5 is a circuit diagram of a test circuit according to a second embodiment.

FIG. 6 is a circuit diagram of a test circuit according to a third embodiment.

### DETAILED DESCRIPTION

According to one embodiment, a test circuit is provided, which includes a plurality of flip-flops operating in synchronization with a clock signal, a timing adjustment circuit to generate a first set signal that provides a command that sets output signals from the flip-flops at a predetermined logic, and a second set signal that provides a command that detects a fault in the output signals from the flip-flops, and to set timing for cancellation of the command of the second set signal, the timing being delayed by n cycles of the clock signal from timing for cancellation of the command of the first set signal, n being an even number, and a fault detection circuit to output a fault detection signal during a period of time from the cancellation of the command of the first set signal to the cancellation of the command of the second set signal, if there is an output signal having a different logic in the output signals from the flip-flops.

Embodiments of the present invention will be described below by referring to the accompanying drawings. Characteristic configurations and operations of the test circuits according to the embodiments will be mainly described below. However, the test circuits may have other configurations or carries out other operations, which are not described herein.

### First Embodiment

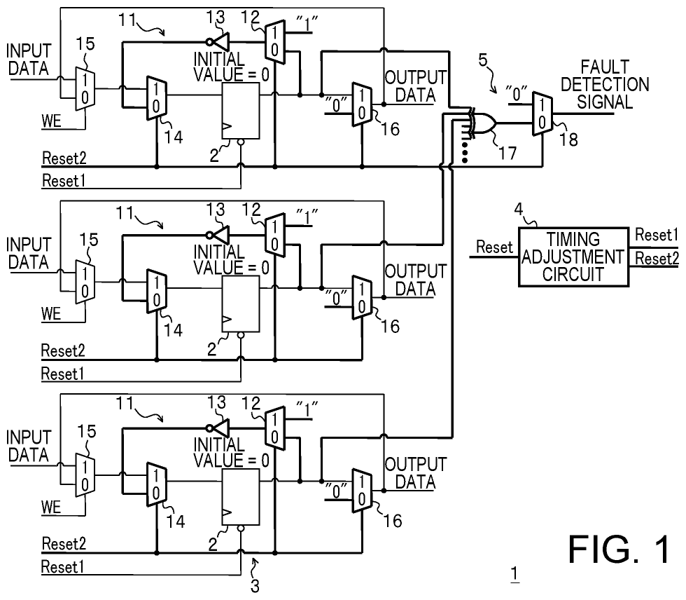

FIG. 1 is a circuit diagram of a test circuit 1 according to a first embodiment. The test circuit 1 shown in FIG. 1 includes a register circuit 3 with a plurality of flip-flops 2, a timing adjustment circuit 4, and a fault detection circuit 5. The test circuit 1 shown in FIG. 1 can detect a fault in which at least one of output signals from the register circuit 3 is stuck at or tied to a first logic or a second logic.

The test circuit 1 shown in FIG. 1 can be used for detecting a fault that at least one of output signals from a circuit having a plurality of flip-flop 2 and not having the resister circuit 3, such as a shift register that will be described later is stuck at a first logic or a second logic.

Thin solid lines in FIG. 1 indicate wiring lines generally provided to the register circuit 3, and broad solid lines indicate wiring lines and circuit components newly needed in addition to those generally provided to the register circuit 3.

The timing adjustment circuit 4 generates a first set signal for commanding that output signals of the flip-flops 2 be set to a predetermined logic, and a second set signal for commanding detection of whether the output signals of the flip-flops 2 have a fault. The timing adjustment circuit 4 also sets the timing of the cancellation of the command provided by the second set signal, which timing is delayed by even number of cycles of the clock signal from the timing for the cancellation of the command provided by the first set signal. The first set signal, for example, resets a first reset signal Reset1, and the second set signal, for example, resets a second reset signal Reset2. In a more specific example, the first set signal represents a case where the first reset signal Reset1 is in a Low state, and the second set signal represents a case where the second reset signal Reset2 is in a Low state.

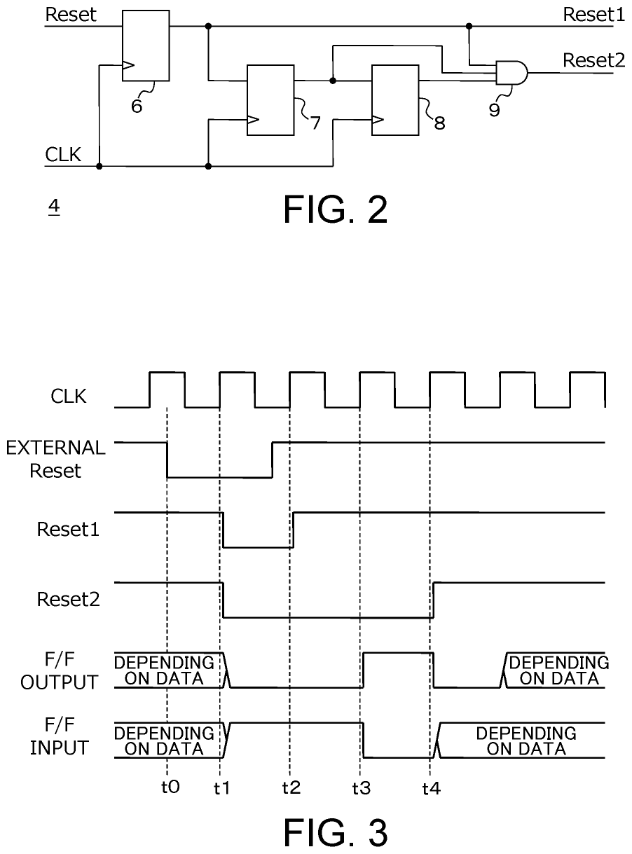

FIG. 2 is a circuit diagram illustrating an example of the timing adjustment circuit 4. The timing adjustment circuit 4 shown in FIG. 2 includes a first flip-flop 6, a second flip-flop 7, a third flip-flop 8, and an AND gate 9. The first flip-flop 6 generates the first reset signal Reset1 by synchronizing an external reset signal (third set signal) Reset with the clock signal CLK.

The second flip-flop 7 generates a signal obtained by delaying the first reset signal Reset1 outputted from the first flip-flop 6, by one cycle of the clock signal CLK. The third flip-flop 8 generates a signal obtained by delaying the output signal from the second flip-flop 7 by one cycle of the clock signal CLK. The AND gate 9 generates the second reset signal

Reset2 that is a logical product signal obtained from the output signals of the first to third flip-flops 6 to 8.

The fault detection circuit 5 outputs a fault detection signal during a period of time from the cancellation of the command provided by the first set signal to the cancellation of the command provided by the second set signal if there is an output signal with a different logic among the output signals from the flip-flops 2. In more detail, the fault detection circuit 5 detects a fault in which at least one of the output signals from the flip-flops 2 is stuck at the first logic and a fault in which at least one of the output signals is stuck at the second logic with different timings during a period of time from the cancellation of the command provided by the first set signal to the cancellation of the command provided by the second set signal. If at least one of the faults is detected, the fault detection circuit 5 outputs the fault detection signal.

Toggle circuits 11 are connected to the register circuit 3 shown in FIG. 1. The toggle circuits 11 invert the output signals from the flip-flops 2 in synchronization with the clock signal CLK during the period of time from the cancellation of the command provided by the first set signal to the cancellation of the command provided by the second set signal, and input the inverted output signals to the corresponding flip-flops 2.

One toggle circuit 11 is provided to each flip-flop 2. Specifically, the toggle circuit 11 includes a first selector 12, an inverter 13, and a second selector 14.

The first selector 12 selects either the first logic (for example High) signal or the output signal from the flip-flop 2 based on the logic of the second reset signal Reset2. Specifically, the first selector 12 selects the first logic signal when the second reset signal Reset2 is High, and selects the output signal from the flip-flop 2 when the second reset signal Reset2 is Low. The logic of the output signal from the first selector 12 is inverted by the inverter 13, and the then the output signal is inputted to the second selector 14.

The second selector 14 selects either the output signal from the third selector 15 or the output signal from the inverter 13 (the signal obtained by inverting the output of the first selector 12) based on the logic of the second reset signal Reset2. Specifically, the second selector 14 selects the output signal from the third selector 15 when the second reset signal Reset2 is High, and selects the signal obtained by inverting the output of the first selector 12 when the second reset signal Reset2 is Low.

Each of the flip-flops 2 shown in FIG. 1 has a reset terminal. The first reset signal Reset1 is inputted to the reset terminal. When the first reset signal Reset1 is in Low, the flip-flop 2 is in a reset state, and the output signal from the flip-flop 2 is in the Low state.

Each of the flip-flops 2 shown in FIG. 1 therefore outputs the output signal in the Low state while the first reset signal Reset1 in the Low state is inputted to the reset terminal, and until the first reset signal Reset1 becomes the High state and the second reset signal Reset2 also becomes the High state, performs an operation to invert the output signal in synchronization with the clock signal CLK according to the toggle circuit 11.

The third selector 15 selects either the input data or the output signal from the fourth selector 16 based on the logic of a write enable signal. Specifically, the third selector 15 selects the input data when the write enable signal is High, and selects the output signal from the fourth selector 16 when the write enable signal is Low.

The fourth selector 16 selects either the output signal from the corresponding flip-flop 2 or the second logic (for example Low) signal based on the logic of the second reset signal Reset2. Specifically, the fourth selector 16 selects the output signal from the corresponding flip-flop 2 when the second reset signal Reset2 is High, and selects the second logic signal when the second reset signal Reset2 is Low. The fourth selector 16 is disposed to set the logic inputted to a circuit connected after the register circuit 3 to conform to the logic of the output from the corresponding flip-flop 2 when the second reset signal Reset2 is in the Low (reset) state. Since all of the flip-flops 2 included in the register circuit 3 shown in FIG. 1 have the reset terminals, all of the fourth selectors 16 select the second logic (Low) signal when the second reset signal Reset2 is in the Low state.

For the sake of simplicity, three flip-flops 2 are shown in FIG. 1. However, the number of flip-flops 2 disposed to the test circuit 1 shown in FIG. 1 is not limited as long as it is two or more.

The fault detection circuit 5 includes, for example, an EXOR gate 17 for calculating exclusive OR, and a fifth selector 18. The output signals from the flip-flops 2 are inputted to the EXOR gate 17. The EXOR gate 17 outputs the first logic (for example High) signal when the output signals from the flip-flops 2 include an output signal having a logic that differs from the logic of the output signals from the other flip-flops 2. Thus, the EXOR gate 17 outputs the Low signal when the logic of the output signals from all of the flip-flops 2 is the same, and outputs the High signal when an output signal with a different logic is included in the output signals from all of the flip-flops 2.

The fifth selector 18 selects either the second logic (for example Low) signal or the output signal from the EXOR gate 17 based on the logic of the second reset signal Reset2. Specifically, the fifth selector 18 selects the second logic signal when the second reset signal Reset2 is High, and selects the output signal from the EXOR gate 17 when the second reset signal Reset2 is Low. The output signal from the fifth selector 18 is the fault detection signal. When the fault detection signal is High, at least one of the output signals from the flip-flops 2 has a stuck-at fault and tied to a logic.

FIG. 3 is an operation timing diagram of the test circuit 1 shown in FIG. 1. The operation of the test circuit 1 shown in FIG. 1 will be described below with reference to FIG. 3. In the initial state, the write enable signal is Low. At time to, the external reset signal Reset changes from High to Low, and then, at the next rising edge of the clock signal CLK (time t1), the first reset signal Reset1 changes from High to Low. This resets the flip-flops 2, and fixes the output signals of the flip-flops 2 at Low. The second reset signal Reset2 also changes from High to Low at time t1. Therefore, the first selector 12 selects the output signal (Low) of the corresponding flip-flop 2, and the inverter 13 inverts the Low output signal and outputs the High signal. Since the second reset signal Reset2 is Low, the second selector 14 selects the High signal outputted from the inverter 13 and inputs the High signal to the corresponding flip-flop 2.

Thereafter, at the rising edge of the clock signal CLK inputted at time t2, the first reset signal Reset1 is in the reset state (Low) and therefore the outputs from the flip-flops 2 are still fixed to Low. However, the output of the first flip-flop 6 included in the timing adjustment circuit 4 shown in FIG. 2 is inverted, and thus the first reset signal Reset1 becomes High to cancel the reset state of the respective flip-flops 2. Thus, after the rising edge of the clock signal CLK is inputted at time t2, the first reset signal Reset1 becomes High, and the reset state of the flip-flops 2 is cancelled.

When the rising edge of the clock signal CLK is inputted at time t3, the outputs of the flip-flops 2 change from Low to High since the reset state of the flip-flops 2 has been cancelled. At this time, the second reset signal Reset2 is still Low. Therefore, the first selector 12 selects the output (High signal) of the corresponding flip-flops 2. The output signal from the first selector 12 is inverted by the inverter 13, and inputted to the corresponding flip-flop 2 via the second selector 14. This changes the input to each flip-flop 2 from High to Low.

At time t2 when the rising edge of the clock signal CLK is inputted, the output of each flip-flop 2 is fixed to Low unless there is a fault. Therefore, the output of the EXOR gate 17 is expected to be Low. If any of the outputs from the flip-flops 2 is stuck at High, the output of the EXOR gate 17 is High. Therefore, a fault in which any of the outputs from the flip-flops 2 is stuck at High can be detected during the period of time from t2 to t3. If the outputs of two or more flip-flops 2 are stuck at High, the output of the EXOR gate 17 is also High. Therefore a fault in which two or more outputs from the flip-flops 2 are stuck at High can be detected. If, however, the outputs from all of the flip-flops 2 are stuck at High, the output of the EXOR gate 17 is kept to Low, and the stuck-at-high fault cannot be detected. However, in practice, the fault in which the outputs from all of the flip-flops 2 are stuck at High cannot happen. Therefore, it would not be necessary to consider the fault in which the outputs from all of the flip-flops 2 are stuck at High.

Thereafter, when a rising edge of the clock signal CLK is inputted at time t3, the outputs of the flip-flops 2 are fixed to High if there is no fault. Therefore, the output of the EXOR gate 17 is expected to be Low. If the output of any of the flip-flops 2 is stuck at Low, the output of the EXOR gate 17 becomes High. Thus, during a period of time from time t3 to the input of the next rising edge of the clock signal CLK (time t4), a fault in which the output of any of the flip-flops 2 is stuck at Low can be detected.

When the rising edge of the clock signal CLK is inputted at time t4, the second reset signal Reset2 outputted from the AND gate 10 included in the timing adjustment circuit shown in FIG. 2 changes from Low to High. This ends the reset period of the test circuit 1 shown in FIG. 1. After time t4, the fourth selector 16 selects the output of the corresponding flip-flop 2. If the write enable signal WE changes from Low to High after time t4, the third selector 15 selects the input data, and the second selector 14 selects the output signal from the third selector 15. Therefore, the input data is inputted to the flip-flops 2.

FIG. 3 shows the example in which after the reset state of the first reset signal Reset1 is cancelled (the first reset signal Reset1 become High), the reset state of the second reset signal Reset2 is cancelled at the second rising edge of the clock signal CLK. However, the reset state of the second reset signal Reset2 may be cancelled at an n-th rising edge of the clock signal CLK where n is an even number.

Thus, when the external reset signal Reset is inputted to the test circuit 1 shown in FIG. 1, the state of the first reset signal Reset1 is changed to Low in synchronization of the next rising edge of the clock signal CLK to reset the flip-flops 2. This makes the outputs of the flip-flops 2 Low if there is no fault. If the output of any of the flip-flops 2 is stuck at High, the output of the EXOR gate 17 becomes High. Therefore, the fault in which the output of any of the flip-flops 2 is stuck at High can be detected. After the first reset signal Reset1 is cancelled, the second reset signal Reset2 is cancelled in synchronization with n-th rising edge of the clock signal CLK where n is an even number. During a period of time from the cancellation of the first reset signal Reset1 to the cancellation of the second reset signal Reset2, each flip-flop 2 performs a toggle operation with the toggle circuit 11 in synchronization with the clock signal CLK. As a result, the detection of the fault in which the output of any flip-flop 2 is stuck at High and the detection of the fault in which the output is stuck at Low may be alternately performed in each cycle.

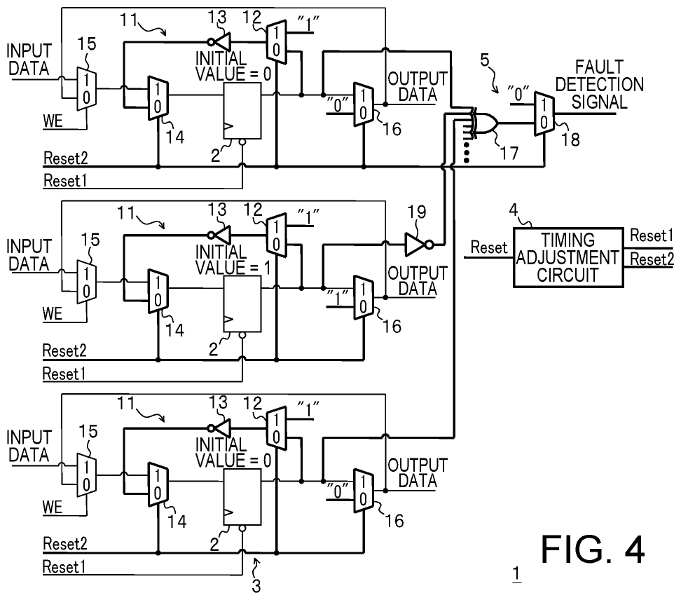

The flip-flops 2 included in the test circuit 1 shown in FIG. 1 have the reset terminals. If a flip-flop 2 has a set terminal, however, a fault in which the output of any flip-flop 2 is stuck at High and a fault in which the output is stuck at Low can be detected in synchronization with the clock signal CLK. FIG. 4 is a circuit diagram of a test circuit 1 including both a flip-flop 2 with a reset terminal and a flip-flop 2 with a set terminal. When the first reset signal Reset1 is Low, the flip-flop 2 having the reset terminal is in the reset state, and its output signal becomes Low. The flip-flop 2 having the set terminal is in a set state, and its output signal becomes High.

While the first reset signal Reset1 at the Low level is inputted to the reset terminal or the set terminal, the flip-flops 2 of the test circuit 1 shown in FIG. 4 output a Low or High output signal. Thereafter, each flip-flop 2 performs an operation to invert the output signal with the toggle circuit 11 in synchronization with the clock signal CLK until the reset state of the first reset signal Reset1 is cancelled (the first reset signal Reset1 become High), and the reset state of the second reset signal Reset2 is cancelled (the second reset signal Reset2 becomes High).

FIG. 4 shows an example in which the uppermost and the lowermost flip-flops 2 have the reset terminals, and the middle flip-flop 2 has the set terminal. However, whether each flip-flop 2 has the reset terminal or the set terminal may be arbitrarily determined. When the second reset signal Reset2 is Low, the fourth selector 16 connected after the flip-flop 2 having the set terminal selects the Low signal. On the other hand, the fourth selector 16 connected after the flip-flop 2 having the reset terminal selects the High signal when the second reset signal Reset2 is Low. This is because the logic of the output data from the test circuit shown in FIG. 1 needs to match the logic of the output data from the corresponding flip-flop when the second reset signal is in the reset state or the set state.

As shown in FIG. 4, an inverter 19 is connected to the output terminal of the flip-flop 2 having the set terminal to set the logic of each signal inputted to the EXOR gate 17 at Low during the reset period.

The reset terminal and the set terminal of the flip-flops 2 may be called “set signal terminals” herein. The flip-flop 2 having the set signal terminal provides an output signal with a predetermined logic while the first set signal is inputted to the set signal terminal, and performs a logic inverting operation in synchronization with the clock signal and in accordance with the toggle circuit after the input of the first set signal to the set signal terminal is stopped and until the timing adjustment circuit outputs the second set signal.

As described above, the test circuits 1 shown in FIGS. 1 and 4 are capable of detecting a fault in which the output of any of the flip-flops 2 is stuck at High and a fault in which the output of any of the flip-flops 2 is stuck at Low can be alternately detected by the EXOR gate 17 in each cycle of the clock signal CLK by the toggle operation of the flip-flop 2 during a period of time in which each flip-flop 2 is initialized, without reading out the data stored in the register circuit 3 including the flip-flops. This enables a simple and fast detection of the fault of the flip-flops 2 with the security being ensured. According to this embodiment, no software is required for writing test data to and reading the test data from the register circuit 3, and checking the read data. The fault detection may be performed with hardware by only adding several circuits and wiring lines to the generally used register circuit 3. This allows a simple and fast fault detection to be performed, and there is no need to develop software for the fault detection.

### Second Embodiment

In the example of the first embodiment, a fault of the flip-flop 2 with the reset terminal or the set terminal is detected. However, a fault of a flip-flop 2 without having the reset terminal or the set terminal may also be possible.

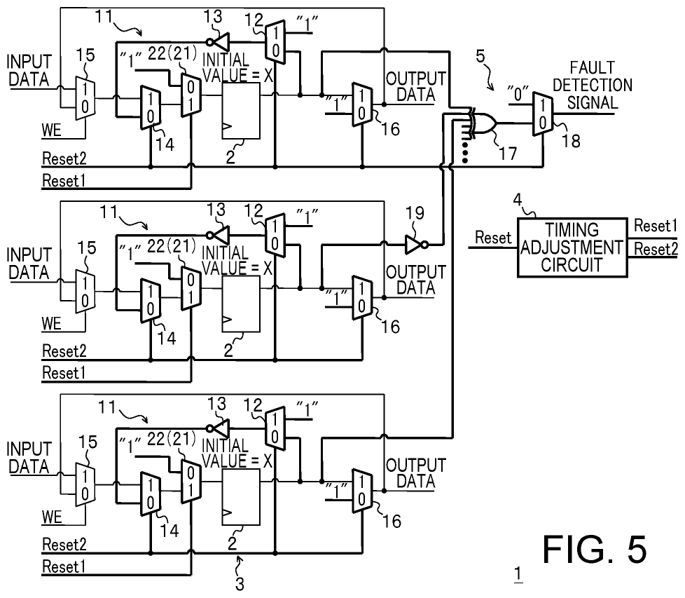

FIG. 5 is a circuit diagram of a test circuit 1 according to a second embodiment. The test circuit 1 shown in FIG. 5 includes flip-flops 2 that do not have a reset terminal or a set terminal, set signal generation circuits 21, a timing adjustment circuit 4, and a fault detection circuit 5.

The circuit configurations of the timing adjustment circuit 4 and the fault detection circuit 5 are the same as those in the test circuit 1 shown in FIG. 1. The set signal generation circuit 21 is connected to at least one signal input terminal of the corresponding flip-flops 2, and generates a signal to be inputted to the corresponding signal input terminal so that an output signal with a predetermined logic is outputted from the corresponding flip-flop 2 when the first set signal is inputted to the set signal generation circuit 21.

Specifically, the set signal generation circuit 21 has a sixth selector 22. The sixth selector 22 selects either a first logic (for example High) signal or the output signal from the second selector 14 based on the logic of the first reset signal Reset1. In more detail, the sixth selector 22 selects the first logic signal when the first reset signal Reset1 is Low, and selects the output signal from the second selector 14 when the first reset signal Reset1 is High.

FIG. 5 shows the example in which the set signal generation circuit 21 that operates in the same manner as the flip-flop 2 with the reset terminal is provided. However, a set signal generation circuit 21 that operates in the same manner as the flip-flop with the set terminal may be provided. In the example of FIG. 5, the signal selected by the fourth selector 16 when the second reset signal Reset2 is Low is the first logic signal (High signal). However, the signal may be the second logic signal (Low). Furthermore, some flip-flops 2 may have the reset terminal or the set terminal, and the set signal generation circuit 21 may be provided to other flip-flops 2 instead of the reset terminal or the set terminal.

Thus, according to the second embodiment, a fault in which the output of any of the flip-flops 2 is stuck at High or Low may be detected by a simple and fast manner as in the first embodiment, even if the flip-flops 2 do not have the reset terminal or the set terminal, by connecting the set signal generation circuits 21 to the input terminals of the flip-flops 2.

### Third Embodiment

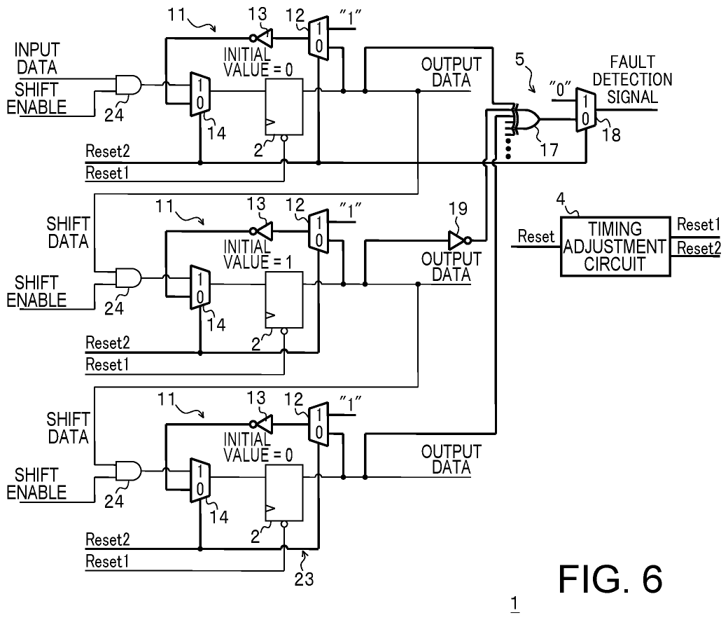

The test circuits 1 in the first and second embodiments detect the faults of the flip-flops 2 included in the register circuits 3. However, the present invention may be used for the test circuit 1 that detects a fault of a plurality of flip-flops 2 included in a shift register 23, as shown in FIG. 6 for example.

Thin solid lines in FIG. 6 indicate circuit components and wiring lines in a general-used shift register 23, and broad solid lines indicate circuit components and wiring lines that are newly added. The shift register 23 has a configuration in which flip-flops are connected in series with AND gates 24 being connected between adjacent flop-flops. The shift register 23 shown in FIG. 6 does not include the third selector 15 and the fourth selector 16 shown in FIG. 1.

Also in the test circuit 1 shown in FIG. 6, a fault in which the output of any of the flip-flops 2 is stuck at High and a fault in which the output of any of the flip-flops 2 is stuck at Low can be alternately detected in each cycle of the clock signal CLK in a period of time from the input of the external reset signal Reset to the cancellation of the reset state of the second reset signal Reset2.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A test circuit comprising:
a plurality of flip-flops operating in synchronization with a clock signal;
a timing adjustment circuit to generate a first set signal that provides a command that sets output signals from the flip-flops at a predetermined logic, and a second set signal that provides a command that detects a fault in the output signals from the flip-flops, and to set timing for cancellation of the command of the second set signal, the timing being delayed by n cycles of the clock signal from timing for cancellation of the command of the first set signal, n being an even number; and
a fault detection circuit to output a fault detection signal during a period of time from the cancellation of the command of the first set signal to the cancellation of the command of the second set signal, if there is an output signal having a different logic in the output signals from the flip-flops.

2. The test circuit according to claim 1, wherein the fault detection circuit is to detect, at different timings, a fault in which an output signal of at least one of the flip-flops is stuck at a first logic and a fault in which an output signal of at least one of the flip-flops is stuck at a second logic during a period of time after the command of the first set signal is executed and until the command of the second set signal is cancelled, and to output the fault detection signal when at least one fault is detected.

3. The test circuit according to claim 1, further comprising toggle circuits to invert the output signals from the flip-flops and to input inverted signals to corresponding flip-flops in synchronization with the clock signal during a period of time from the cancellation of the command of the first set signal to the cancellation of the command of the second set signal.

4. The test circuit according to claim 3, wherein:
at least one of the flip-flops comprises a set signal terminal to which the first set signal is inputted; and
the at least one of the flip-flops comprising the set signal terminal outputs the output signal having the predetermined logic while the first set signal is being inputted to the set signal terminal, and performs a logic inverting operation in synchronization with the clock signal in accordance with the corresponding toggle circuit after the input of the first set signal to the set signal generation circuit is stopped and before the cancellation of the command of the second set signal.

5. The test circuit according to claim 3, further comprising a set signal generation circuit connected to a signal input terminal of at least one of the flip-flops, to generate a signal to be inputted to the signal input terminal so that the output signal having the predetermined logic is outputted from the at least one of the flip-flops when the command of the first set signal is executed,
wherein the at least one of the flip-flops having the signal input terminal to which the set signal generation circuit is connected outputs the output signal having the predetermined logic while the first set signal is being inputted to the set signal generation circuit, and performs a logic inverting operation in synchronization with the clock signal in accordance with the corresponding toggle circuit after the input of the first set signal to the set signal generation circuit is stopped and before the cancellation of the command of the second set signal.

6. The test circuit according to claim 1, wherein the fault detection circuit outputs the fault detection signal based on an exclusive OR of the output signals from the flip-flops.

7. The test circuit according to claim 1, wherein the timing adjustment circuit generates the first set signal by synchronizing an initialization signal with the clock signal, and the second set signal, the command of which is executed at the same time as the command of the first set signal is executed, and cancelled by being delayed by n cycles of the clock signal after the command of the first set signal is cancelled.

8. A test method comprising:
generating a first set signal that provides a command that output signals from flip-flops operating in synchronization of a clock signal be set at a predetermined logic, and a second set signal that provides a command that a fault in the output signals from the flip-flops be detected, and setting timing for cancellation of the command of the second set signal, which is delayed by n cycles of the clock signal from timing for cancellation of the command of the first set signal, ne being an even number; and
outputting a fault detection signal during a period of time from the cancellation of the command of the first set signal to the cancellation of the command of the second set signal, if there is an output signal having a different logic in the output signals from the flip-flops.

9. The test method according to claim 8, wherein the fault detection circuit is to detect, at different timings, a fault in which an output signal of at least one of the flip-flops is stuck at a first logic and a fault in which an output signal of at least one of the flip-flops is stuck at a second logic during a period of time after the command of the first set signal is executed and until the command of the second set signal is cancelled, and to output the fault detection signal when at least one fault is detected.

10. The test method according to claim 8, wherein toggle circuits is provided to invert the output signals from the flip-flops and to input inverted signals to corresponding flip-flops in synchronization with the clock signal during a period of time from the cancellation of the command of the first set signal to the cancellation of the command of the second set signal.

11. The test method according to claim 10, wherein:
at least one of the flip-flops is provided with a set signal terminal to which the first set signal is inputted; and
the at least one of the flip-flops comprising the set signal terminal outputs the output signal having the predetermined logic while the first set signal is being inputted to the set signal terminal, and performs a logic inverting operation in synchronization with the clock signal in accordance with the corresponding toggle circuit after the input of the first set signal to the set signal generation circuit is stopped and before the cancellation of the command of the second set signal.

12. The test method according to claim 10, wherein:
a set signal generation circuit connected to a signal input terminal of at least one of the flip-flops is provided, to generate a signal to be inputted to the signal input terminal so that the output signal having the predetermined logic is outputted from the at least one of the flip-flops when the command of the first set signal is executed,
the at least one of the flip-flops having the signal input terminal to which the set signal generation circuit is connected outputs the output signal having the predetermined logic while the first set signal is being inputted to the set signal generation circuit, and performs a logic inverting operation in synchronization with the clock signal in accordance with the corresponding toggle circuit after the input of the first set signal to the set signal generation circuit is stopped and before the cancellation of the command of the second set signal.

13. The test method according to claim 8, wherein the fault detection circuit outputs the fault detection signal based on an exclusive OR of the output signals from the flip-flops.

14. The test method according to claim 8, wherein the timing adjustment circuit generates the first set signal by synchronizing an initialization signal with the clock signal, and the second set signal, the command of which is executed at the same time as the command of the first set signal is executed, and cancelled by being delayed by n cycles of the clock signal after the command of the first set signal is cancelled.
